(19) United States
(12) Patent Application Publication
(10) Pub. No.: US 2009/0298206 A1
(43) Pub. Date: Dec. 3, 2009

(54) METHOD AND APPARATUS TO MINIMIZE STRESS DURING REFLOW PROCESS

(75) Inventors: Eric Duchesne, Granby (CA); Julien Sylvestre, Chambly (CA)

Correspondence Address: Oppenheimer Wolff & Donnelly LLP, Plaza VII, Suite 3300, 45 South Seventh Street, Minneapolis, MN, 55402-1609, US

(73) Assignee: International Business Machines, Armonk, NY (US)

(21) Appl. No.: 12/127,895

(22) Filed: May 28, 2008

(51) Int. Cl. H01L 21/66

(52) U.S. Cl. 438/16; 257/E21.521

(57) ABSTRACT

Utilizing an appropriately configured laser interferometer, the warpage of a silicon chip can be easily monitored during the solder reflow attachment process in an effort to determine the amount of stress encountered by the chip. Warpage measurements can then be continuously monitored throughout the process and related data can be stored to easily suggest the level of warpage generated by various processing parameters. By dynamically monitoring warpage in conjunction with processing parameters, a correlation can be established between the various parameters chosen, and resulting warpage. Based upon this correlation, the evaluators can easily identify those parameters which produce minimum stress, thus avoiding potential for breakage and damage during reflow operations.

### FIELD OF THE INVENTION

The present invention provides a method for more efficiently carrying out the reflow chip attachment process for flip chip semiconductors. More specifically, the present invention provides an evaluation tool to minimize stress during this chip attachment process.

### BACKGROUND OF THE INVENTION

During the manufacturing of semiconductors, some type of chip attachment process is necessary for joining a silicon chip to related components such as a circuit board, carrier, etc. C4 mounting (flip chip) is one such attachment methodology which is widely utilized in the semiconductor manufacturing industry. Unfortunately, the chip attachment process utilized, and specifically the solder reflow process used during C4 mounting, can create large stresses on the chip due to various sources. Parameters controlling these stresses may include solder creep, cooling rates, solder alloy compositions, solder microstructure, or interconnect geometry. Various values of these parameters can result in sufficiently large stresses on the chip to break already brittle component structures.

Current methodologies to avoid this undesirable stress primarily involve trial and error manufacturing as well as numerical simulations. More specifically, a number of parts are manufactured utilizing a predetermined set of parameters, and then the results of this process are analyzed. These manufactured parts are closely examined and tested to determine the existence of flaws and/or undesirable results after the completion of the process. If such undesirable results are found, certain parameters are changed in an attempt to better improve the manufacturing process. Utilizing these modified parameters, a next set of parts is then manufactured. On the other hand, numerical simulations of the chip joining process are technically challenging and they can be imprecise due to the poor current knowledge of the creep properties of soldering alloys.

In the context of the flip chip attachment processes, the attachment of multiple chips is first carried out utilizing a first set of parameters, and then an analysis of the results is undertaken. The selected parameters involve temperature levels, temperature profiles, attachment geometries, etc. Based upon the results of this analysis, processing parameters are then changed and the reflow process is repeated using another set of parts. Eventually, a result is obtained which is relatively more desirable, when compared with other results. Unfortunately, this trial and error process requires a large number of parts or components to be utilized for analysis purposes alone. Further, by continuing to iteratively process parts, long time periods are required thus prolonging the analysis process. For example, it is not uncommon for 100 parts to be processed in one run, and then subsequently analyzed to determine the efficiency of the selected parameters. Subsequently, another 100 parts may be necessary for a second analysis step, thus requiring over 200 parts alone simply for evaluation purposes. As anticipated, a more efficient and effective method to optimize manufacturing is desirable.

### BRIEF SUMMARY OF THE INVENTION

The present invention optimizes manufacturing processes, and minimizes stress caused by solder reflow by performing continuous monitoring during the reflow process. More specifically, the chips going through the reflow process are closely monitored to track any warpage that occurs. During this monitoring, data is collected related to the above-mentioned warpage, in conjunction with data related to processing parameters being utilized. For example, a thermal profile can be obtained while also monitoring the above-mentioned warpage. By correlating these two elements alone, thermal profiles can be optimized to most efficiently carry out the solder reflow process of flip chip attachment. Likewise, other parameters can also be optimized such as connection geometries, solder bump dimensions, solder alloy compositions, etc. Because monitoring is done dynamically, data related to warpage profiles are available immediately following the manufacturing process, and can be utilized to immediately analyze results.

As a basic concept, the inventors have discovered that continuous monitoring of chip warpage throughout the solder reflow process can provide valuable information indicating a correlated amount of stress being placed upon the chip. Consequently, by monitoring warpage during multiple reflow operations, parameters can thus be chosen to optimize warpage and also minimize solder induced stress. Utilizing this discovery, the optimization of manufacturing processes is easily and quickly achieved without requiring the manufacturing of multiple parts and the need for multiple processing runs.

In order to obtain the above-referenced data, the chip warpage is monitored utilizing a laser interferometer, which is both very precise and immediate. This measurement scheme doesn't require mechanical contact with the chip, so that the mechanical state of the device under test is not perturbed by the measurement system. By digitally processing the data acquired from the interferometer, warpage is directly and easily seen. The existence of warpage can then be easily analyzed in conjunction with other data that are obtained during the attachment process. By analyzing multiple data sources simultaneously, various factors of the process can be easily correlated, such as warpage along with temperature or solder alloy composition, for instance.

### BRIEF DESCRIPTION OF THE DRAWINGS

Further objects and advantages of the present invention can be seen by reading the following detailed description, in conjunction with the drawings in which:

FIG. 1 is a block diagram illustrating the monitoring setup utilized during solder reflow processes;

FIG. 2 is a flow chart illustrating the process utilized by the present invention;

FIG. 3 is a graph illustrating one thermal profile utilized during solder reflow which is overlaid upon related warpage measurements; and

FIG. 4 is a similar graphical illustration showing related thermal profiles and warpage measurements for multiple processing parameters.

### DETAILED DESCRIPTION OF THE INVENTION

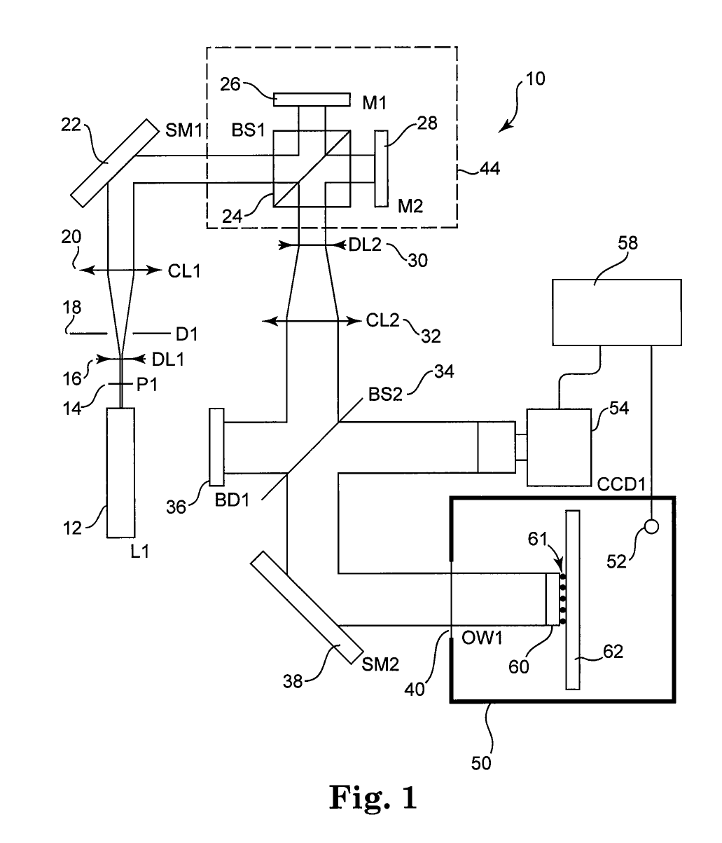

To optimize the process of solder reflow attachment, the present invention carries out the reflow process utilizing a predetermined set of parameters while continuously monitoring many aspects of the process. Most significantly, the chips being attached to substrates using this process are dynamically monitored for ongoing warpage. Referring to FIG. 1, there is generally illustrated an optical measurement system 10 which is capable of continuously monitoring warpage. Optical measurement system 10 includes a laser 12 for producing a desired optical signal. The output of laser 12 is passed through a first polarizer 14, a first divergent lens 16, a first diaphragm 18 and a first convergent lens 20 before being projected upon a first steering mirror 22. The optical signal is then reflected from first steering mirror 22 to a first beam splitter 24 which is capable of directing the signal in multiple directions. More specifically, first beam splitter 24 will provide a portion of the signal to first flat mirror 26 while a second portion of the signal is provided to second flat mirror 28. This structure, generally referred to as a Michelson interferometer 44, is utilized to create a desired interference pattern, as recognized by those skilled in the art. Eventually, beam splitter 24 will thus direct an appropriate optical signal to second divergent lens 30, then to a second convergent lens 32 and eventually to a second beam splitter 34. From second beam splitter 34 signals are then appropriately directed to a beam dump element 36 to absorb undesired reflections, and a second steering mirror 38. Eventually, the evaluation signal is reflected from second steering mirror 38, and directed through an optical window 40 which exists in a processing chamber 50. Within processing chamber 50 is the chip 60 which is undergoing the reflow operations being evaluated. The chip 60 is being attached via an array of solder balls 61 to a substrate 62. As will be anticipated, processing chamber 50 may likely include a thermal chamber capable of varying temperatures in a very controlled manner. In order to monitor temperatures within processing chamber 50, a thermal sensor 52 is positioned within the chamber itself. Naturally, several additional process characteristics can easily be monitored.

As generally discussed above, the optical components illustrated in FIG. 1 provide an optical signal which is directed towards chip 60. Similarly, a reflection signal is produced and reflected back to steering mirror 38 and beam splitter 34 which is presented to a photosensitive element or camera 54. As will be appreciated by those skilled in the art, the interference pattern formed by the Michelson interferometer 44 will be distorted by any deviation from a perfectly flat state of the chip surface. During processing, any warpage, movement or repositioning of chip 60 will cause related changes in this interference pattern and will appropriately be detected by camera 54.

As further illustrated in FIG. 1, camera 54 and thermal sensor 52 are both connected to a data collection system 58 which is capable of continuously monitoring the outputs of these two components and storing data generated during operating processes. Data collection system 58 is further capable of analyzing the data collected during the reflow process and storing the results of this analysis. Although not shown in FIG. 1, data collection system 58 may well be connected to further computing systems for additional data processing and/or storage. The general configuration illustrated in FIG. 1 provides one method for creating an interferometer capable of measuring surface movements and, in this application, chip warpage. Naturally, variations to this system could be easily implemented and utilized to achieve the same or similar results.

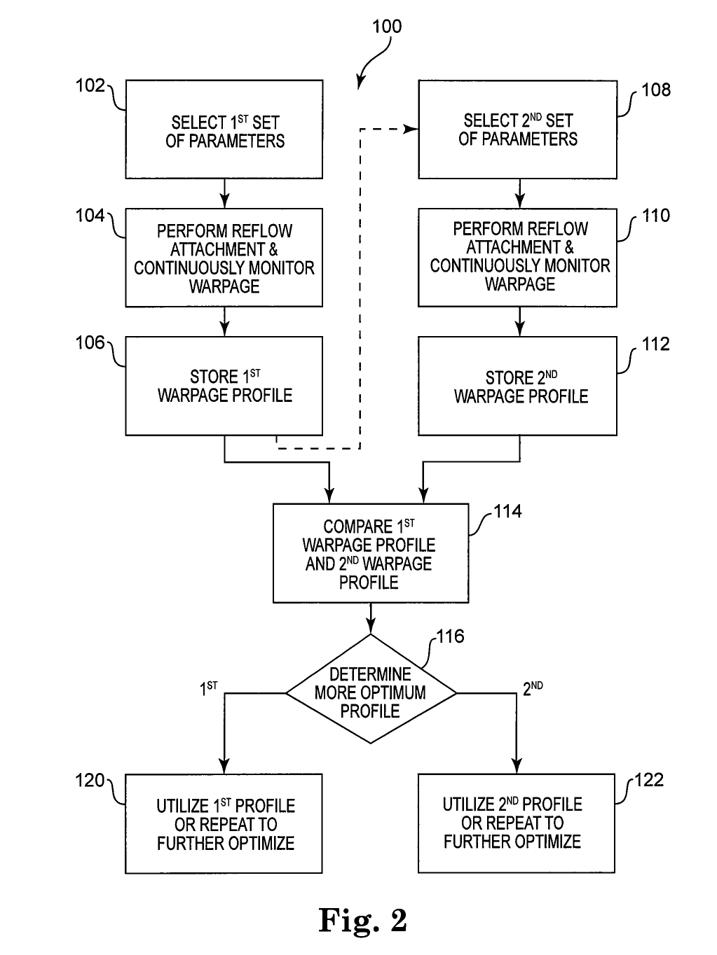

Utilizing the system illustrated in FIG. 1, the present invention carries out a process which is designed to optimize the solder reflow process. Such an optimization process will necessarily minimize stresses generated during the reflow process, possibly subjected to other engineering constraints such as total reflow time, reflow furnace capabilities, etc. Referring to FIG. 2, a flow chart illustrates this optimization process 200. Initially, at step 102 a first set of parameters is selected for the solder reflow process. Next, at step 104 the reflow process itself is carried out utilizing the selected parameters, while also continuously monitoring any warpage that exists in the chip. Based upon this continuous monitoring of warpage and the reflow process itself, a first warpage profile is created and stored. To analyze the process and to determine optimum characteristics, a second set of parameters is then chosen at step 108. Naturally, it is highly likely that this selection of second parameters would occur after the first attachment process is completed. However, this may be done in parallel using two systems, or may be done at alternative times, depending upon the needs and desires of individuals carrying out the analysis. That said, once the second set of parameters is chosen, the reflow attachment process is again carried out utilizing these parameters and chip warpage is again continuously monitored. Next, at step 112, a second warpage profile is generated and stored utilizing the monitoring portions of step 110.

After performance of at least two reflow attachment processes, the first warpage profile and the second warpage profile are compared at step 114. Naturally, the goal of this process is to determine the optimum profile which produces minimum stress (i.e., minimum warpage). Once analyzed, a determination is made at step 116 to determine which profile is more optimum. If the first profile is determined to be more optimum, a decision is made at step 120 to either utilize this profile for continuous processing, or to repeat in order to further assess additional sets of parameters. Likewise, step 122 allows the selection of the second set of parameters or the potential for further evaluation of additional potential parameters.

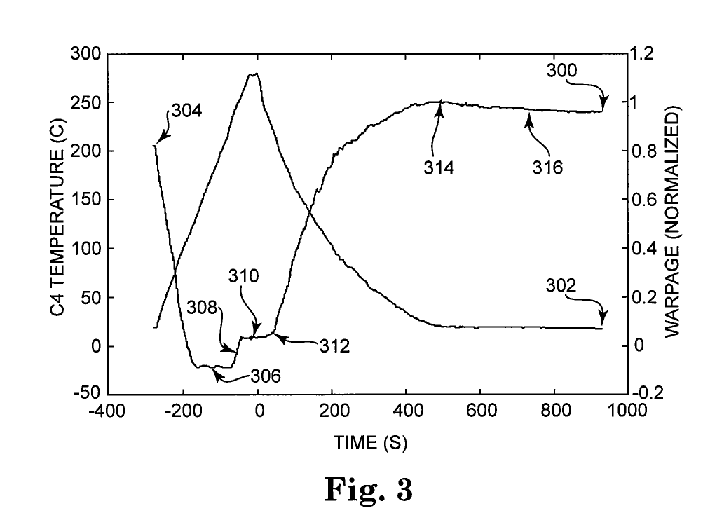

Utilizing the monitoring steps outlined above generally produces an indication of chip warpage as the chip goes through the reflow process. FIG. 3 shows a graphical illustration of the warpage profile over time. Specifically, line 300 illustrates warpage (in arbitrary units) as the chip goes through the reflow process. For comparison purposes, it is beneficial to include a second graphing line 302 which is indicative of the temperature profile utilized during this reflow process.

Looking more specifically at curve 300, indicating the warpage, several components of this graph are significant for solder reflow operations. Initially, an initial warpage slope 304 is produced as temperature increases within the chamber. Next an initial slope 308 is indicative of liquification while a flattening portion 310 occurs while solder is in a substantially liquid state, and little stress is present in the chip. Next, as the temperature begins to drop within the chamber itself, solidification occurs at point 312 thus resulting in an increase in warpage as time goes on. At some point which is usually very close to room temperature, a peak stress 314 can be detected, followed by a relaxation stage 316 during which the temperature is fixed at room temperature, and stress is gradually relieved by the creep deformation of the solder joints. In the solder reflow process, these stages are typically very identifiable and will be illustrated in the various warpage measurements discovered.

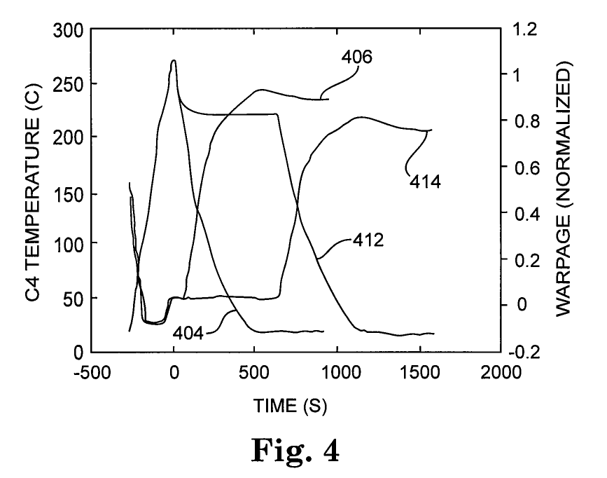

As discussed above, the purpose of the present invention is to provide optimized conditions for solder reflow which will produce minimum stress upon the chip itself. Referring to FIG. 4, two sets of warpage curves are illustrated. In essence, two warpage profiles are shown, a first warpage profile 402 made up of a first temperature trace 404 and a first warpage trace 406. Similarly, a second warpage profile is shown which includes a second temperature trace 412 and a second warpage trace 414. For reference, units of temperature are shown on the left side of this graph, which indicate temperatures of first temperature trace 404 and second temperature trace 412. Similarly related warpage values are shown on the right side of this graph which correspond to first warpage trace 406 and second warpage trace 412.

As illustrated in FIG. 4, second warpage trace 412 indicates a lower peak warpage value, and thus lower peak stress levels are experienced utilizing the related temperature profile. As such, this may be selected as the “most optimum” operating profile under which to perform solder reflow operations. Naturally, those skilled in the art will recognize that many different considerations, beyond peak stress itself, may be considered. In other circumstances, an “optimum” set of parameters may be based upon other factors, such as the rate of warpage over time. In yet another set of evaluations, “optimum” parameters may be a combination of peak warpage and warpage rates over time. Alternatively, minimum time to relaxation may be considered. That said, the present invention provides an easy system and method to achieve this analysis and perform optimization using various criteria as established by the evaluator.

As illustrated in FIGS. 3 & 4 above, peak warpage will typically occur for a period of time prior to relaxation. Generally, the period of peak warpage is relative short when compared with the overall reflow time period. This relatively short period of time makes it very important to monitor warpage continuously so this peak can be determined. If measurements are not frequent enough, the time period of peak warpage could be missed. In a preferred embodiment of the invention, measurements will be taken each second, and perhaps more frequently. Ideally, the monitoring would be done continuously, thus providing the ability to produce an accurate profile showing exactly how the chip reacts during the reflow process. That said, there is often a balance between sampling rate and the overall amount of data that is appropriate.

While certain embodiments of the invention have been described above, they are not considered to be limiting in any way but rather illustrative of the concepts of the present invention. That said, the applicant intends the invention to include all variations coming within the scope and spirit of the following claim.

1. A method to optimize the manufacturing of a flip chip package so that stress is minimized during a solder reflow of the chip joining process, comprising:
preparing a first sample chip and a second sample chip for the solder reflow of the chip joining process;
performing the solder reflow process on the first sample chip using a first set of parameters while continuously monitoring a back surface of the first sample chip during a first period of time to measure warpage that occurs during the solder reflow process, wherein the continuous monitoring of the back surface of the first sample chip is achieved by non-contact monitoring with a laser interferometer, wherein a first warpage profile is obtained and stored which corresponds to the monitored warpage of the first sample obtained throughout the continuously monitored first period of time;
performing the solder reflow process on the second sample chip using a second set of parameters while continuously monitoring a back surface of the second sample chip during a second period of time to measure warpage that occurs during the solder reflow process, wherein the continuous monitoring of the back surface of the second sample chip is achieved by non-contact monitoring with a laser interferometer, wherein a second warpage profile is obtained and stored which corresponds to the monitored warpage of the second sample obtained throughout the continuously monitored second period of time; and
analyzing the first warpage profile and the second warpage profile to determine if the first set of parameters or the second set of parameters produces more optimum reflow conditions and thus provides a more efficient manner of performing the solder reflow of the chip joining process, wherein the optimum reflow conditions are determined by examining the first warpage profile to determine an identified peak warpage value and examining the second warpage profile to determine a second identified peak warpage value, and the optimum reflow conditions are determined to be those conditions producing a smaller peak warpage value.

2. The method of claim 1, wherein the first set of parameters includes one or more of temperature levels, temperature profiles, connection geometries, solder bump dimensions, and solder alloy compositions.

3. The method of claim 1, wherein the second set of parameters includes one or more of temperature levels, temperature profiles, connection geometries, solder bump dimensions, and solder alloy compositions.

4. The method of claim 1, wherein the first period of time and the second period of time are equal.

5. The method of claim 1, wherein the optimum reflow conditions further comprise one or more of a warpage rate over time and a minimum time to relaxation.
